(19) United States
(12) Patent Application Publication
(10) Pub. No.: US 2006/0189079 A1
(43) Pub. Date: Aug. 24, 2006

(54) Method of forming nanoclusters

(76) Inventors: Tushar P. Merchant, Gilbert, AZ (US); Ramachandran Muralidhar, Austin, TX (US); Rajesh A. Rao, Austin, TX (US); Matthew W. Stoker, Mesa, AZ (US); Sherry G. Straub, Pflugerville, TX (US)

Correspondence Address: FREESCALE SEMICONDUCTOR, INC.;LAW DEPARTMENT, 7700 WEST PARMER LANE MD:TX32/PL02, AUSTIN, TX, 78729, US

(21) Appl. No.: 11/065,519

(22) Filed: Feb. 24, 2005

(51) Int. Cl. H01L 21/336

(52) U.S. Cl. 438/260

(57) ABSTRACT

A method for forming nanoclusters includes providing a semiconductor substrate; forming a dielectric layer over the semiconductor substrate, exposing the semiconductor substrate to a first flux of atoms to form first nuclei on the dielectric layer, exposing the first nuclei to a first inert atmosphere after exposing the semiconductor substrate to the first flux, and exposing the semiconductor substrate to a second flux of atoms to form second nuclei after exposing the first nuclei to an inert atmosphere.

### FIELD OF THE INVENTION

This invention relates generally to semiconductor devices, and more specifically, to forming nanoclusters.

### BACKGROUND

Electrically erasable programmable read only memory (EEPROM) structures are commonly used in integrated circuits for non-volatile data storage. EEPROM device structures commonly include a polysilicon floating gate formed over a tunnel dielectric, which is formed over a semiconductor substrate, to store charge. As device dimensions and power supply voltages decrease, the thickness of the tunnel dielectric cannot correspondingly decrease in order to prevent data retention failures. An EEPROM device using isolated silicon nanoclusters as a replacement to the floating gate does not have the same vulnerability to isolated defects in the tunnel dielectric and thus, permits scaling of the tunnel dielectric and the operating voltage without compromising data retention.

In order to have a significant memory effect as measured by the threshold voltage shift of the EEPROM device, it is necessary to have a high density of silicon nanoclusters of approximately 1E12 nanoclusters per cm². One method to achieve such a density of nanoclusters is to fabricate the nanoclusters using ultra high vacuum chemical vapor deposition (UHVCVD) using disilane (Si₂H₆). However, the resulting nanoclusters vary in size distribution, which decreases reliability of the EEPROM devices. To improve reliability, a method to form nanoclusters with narrow size distributions at desired densities is needed.

### BRIEF DESCRIPTION OF THE DRAWINGS

The present invention is illustrated by way of example and is not limited by the accompanying figures, in which like references indicate similar elements.

FIG. 1 illustrates a nucleation and growth graph as is known in the industry;

FIG. 2 illustrates a cross section of a portion of a semiconductor substrate when exposed to a first flux of atoms in accordance with an embodiment of the present invention;

FIG. 3 illustrates the semiconductor substrate of FIG. 2 after a first anneal in accordance with an embodiment of the present invention;

FIG. 4 illustrates the semiconductor substrate of FIG. 3 exposed to a second flux of atoms in accordance with an embodiment of the present invention;

FIG. 5 illustrates the semiconductor substrate of FIG. 4 after a second anneal in accordance with an embodiment of the present invention; and

FIG. 6 illustrates the semiconductor substrate of FIG. 5 after forming a dielectric layer and an electrode layer in accordance with an embodiment of the present invention.

Skilled artisans appreciate that elements in the figures are illustrated for simplicity and clarity and have not necessarily been drawn to scale. For example, the dimensions of some of the elements in the figures may be exaggerated relative to other elements to help improve the understanding of the embodiments of the present invention.

### DETAILED DESCRIPTION OF THE DRAWINGS

FIG. 1 illustrates a nucleation and growth graph 10 as is known in the industry. The x-axis 12 is the deposition time and the y-axis 14 is the nanocluster density. The first phase 16 is the incubation phase where adatoms begin to form on the dielectric surface. These adatoms can be directly deposited from the gas phase (physical vapor deposition) or result from chemical reaction of an active species on the surface (chemical vapor deposition). At this stage these adatoms randomly diffuse on the surface. Once a sufficient concentration of adatoms is achieved, collisions between adatoms lead to the formation of nuclei which can also disassociate. The smallest nuclei that has a greater probability of growth rather than dissociation is called a critical nuclei. During the second phase 18 which is the nucleation phase, several nuclei larger than the critical size are formed and the nanocluster density increases rapidly with time. The third phase 20 is the growth stage where the nanocluster density is saturated so it does not change greatly and instead the nuclei grow into large nuclei or nanoclusters. Any new adatoms on the surface incorporate with existing nuclei instead of forming new nuclei because of the large exclusion zone surrounding the existing nuclei. In the exclusion zone, the adatoms are depleted because they are captured by the stable nuclei or nanocluster. When the exclusion zones of all the nanocrystals overlap the entire dielectric layer surface area, new nucleation is prevented. In the fourth phase 22, the coalescence phase, the nanoclusters begin coalescing or merging together so that the nanocrystal density decreases dramatically and eventually, if processing continues, will form an almost uniform complete layer. This nucleation and growth graph 10 shows the common phase transformations that a nanocluster undergoes during deposition provided the deposition time is long enough to allow all of the phases to occur.

The inventors have discovered that annealing the nanoclusters (also called nanocrystals) after depositing them enlarges the exclusion zone and suppresses new nucleation. Thus, by annealing after forming nanoclusters a narrow size distribution can be achieved. In addition, this process allows for increased nanocluster density, which desirably allows more data to be stored. In one embodiment, a first group of nuclei are deposited over a dielectric layer on a semiconductor substrate and then annealed to form a first group of nanoclusters. Next, a second group of nuclei are deposited. Due to the enlarged exclusion zones, most new adatoms on the surface incorporate into existing nanoclusters, and the formation of the second group of smaller-sized nuclei is suppressed; however, new nuclei are formed. Then, the first group of nanoclusters and the second group of nuclei are annealed to form nanoclusters that are substantially homogenously sized over the dielectric layer.

In one embodiment, the nanoclusters are formed by providing a semiconductor substrate, forming a dielectric layer over the semiconductor substrate, exposing the semiconductor substrate to a first flux of atoms to form first nuclei on the dielectric layer, exposing the first nuclei to a first inert atmosphere after the exposing the semiconductor substrate to the first flux, and exposing the semiconductor substrate to a second flux of atoms to form second nuclei after the exposing the first nuclei to an inert atmosphere. In one embodiment, the exposing the semiconductor substrate to the first flux of atoms comprises forming the first nuclei by a method selected from the group consisting of chemical vapor deposition (CVD), atomic layer deposition (ALD), and physical vapor deposition (PVD). In one embodiment, 3. The method of claim 1, wherein the exposing the semiconductor substrate to the second flux of atoms comprises forming the second nuclei by a method selected from the group consisting of chemical vapor deposition (CVD), atomic layer deposition (ALD), and physical vapor deposition (PVD). In one embodiment, exposing the semiconductor substrate to a first flux of atoms is performed at a first temperature, the exposing the first nuclei to a first inert atmosphere is performed at a second temperature, and the second temperature is greater than or equal to the first temperature. In one embodiment, exposing the semiconductor substrate to the first flux of atoms comprises exposing the substrate to a chemistry selected from the group consisting of disilane, silane, germane and digermane. In one embodiment, exposing the semiconductor substrate to the second flux of atoms comprises exposing the substrate to a chemistry selected from the group consisting of disilane, silane, germane and digermane.

In one embodiment, exposing the first nuclei to a first inert atmosphere comprises exposing the first nuclei to an element selected from the group consisting of nitrogen, argon and helium. In one embodiment, exposing the semiconductor substrate to a first flux of atoms, the exposing the first nuclei to a first inert atmosphere, and the exposing the semiconductor substrate to a second flux of atoms occurs within a same tool without breaking vacuum. In one embodiment, the nuclei are exposed to a second inert atmosphere after the exposing the semiconductor substrate to a second flux of atoms. In one embodiment, exposing the semiconductor substrate to a second flux of atoms is performed at a third temperature, the exposing the second nuclei to a second inert atmosphere is performed at a fourth temperature, and the fourth temperature is greater than or equal to the third temperature. In one embodiment, exposing the semiconductor substrate to a first flux of atoms is performed at a first temperature, the exposing the first nuclei to a first inert atmosphere is performed at a second temperature, and the first temperature is approximately equal to the third temperature and the second temperature is approximately equal to the fourth temperature. In one embodiment, the first temperature and the third temperature is between 400 and 600 degrees Celsius; and the second temperature and the fourth temperature are between 400 and 1,000 degrees Celsius.

In one embodiment, a method of forming nanoclusters includes providing a substrate, forming a dielectric layer overlying the substrate, placing the substrate in a deposition chamber, flowing a first precursor gas into the deposition chamber during a first phase to nucleate first nanoclusters on the dielectric layer, flowing a second precursor gas into the deposition chamber during a second phase to nucleate second nanoclusters on the dielectric layer, and performing a first anneal after the flowing the first precursor gas and before the flowing the second precursor gas. In one embodiment, a second anneal is performed after flowing the second precursor gas. In one embodiment, the first precursor gas and the second precursor gas comprise substantially the same gas. In one embodiment, the first precursor gas and the second precursor gas are different gases. In one embodiment, the first precursor gas and the second precursor gas are selected from the group consisting of disilane, silane, germane and digermane. In one embodiment, flowing a first precursor gas, flowing a second precursor gas, and performing a first anneal are performed in vacuum.

In one embodiment, a method of forming nanoclusters includes providing a substrate, forming a dielectric layer overlying the substrate, placing the substrate in a deposition chamber, flowing a first precursor gas into the deposition chamber during a first phase to nucleate first nanoclusters on the dielectric layer with first predetermined conditions existing within the deposition chamber for a first time period, ending the flowing of the first precursor gas into the deposition chamber, performing an intermediate anneal to grow the first nanoclusters, and flowing a second precursor gas into the deposition chamber during a second phase to nucleate second nanoclusters on the dielectric layer with second predetermined conditions existing within the deposition chamber for a second time period. In one embodiment, the first precursor gas and the second precursor gas comprise the same gas.

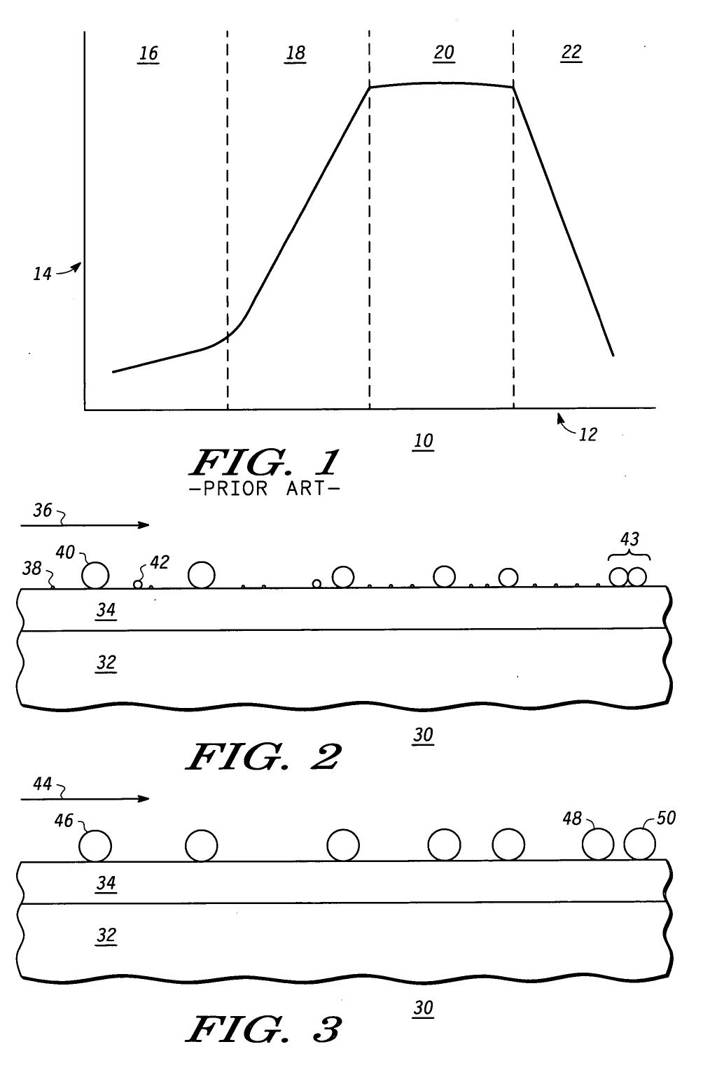

FIG. 2 illustrates a cross-section of a portion of a semiconductor device 30, which in a preferred embodiment is a memory device, having a semiconductor substrate 32, a tunnel dielectric layer 34, nuclei 42, adatoms 38, and nanoclusters 40, and doublets 43. The semiconductor substrate 32 can be any semiconductor material or combinations of materials, such as gallium arsenide, silicon germanium, silicon-on-insulator (SOI) (e.g., fully depleted SOI (FDSOI)), silicon, monocrystalline silicon, the like, and combinations of the above. The tunnel dielectric layer 34 may be any dielectric material, such as silicon dioxide or a high-k (high dielectric constant) material, such as hafnium oxide. In addition, the tunnel dielectric layer 34 may be a stack of dielectric materials, such as a layer of silicon dioxide and hafnium oxide. In one embodiment, the tunnel dielectric layer 34 is approximately 2-10 nanometers of silicon dioxide formed by thermal growth. The tunnel dielectric layer 34 can be formed by any process, such as thermal growth, chemical vapor deposition (CVD), which includes any CVD process that is plasma enhanced or thermal, atomic layer deposition (ALD), physical vapor deposition (PVD), the like, and combinations of the above.

In a preferred embodiment, the tunnel dielectric layer 34 is a high dielectric constant (hi-k) dielectric or a combination of materials, where at least one of the materials is a hi-k dielectric. Any hi-k dielectric may be used, such as hafnium oxide, zirconium oxide, the like, and combinations of the above. In one embodiment, the tunnel dielectric layer 34 includes silicon dioxide or the like. For example, the tunnel dielectric layer 34 may be hafnium oxide with an underlying layer of silicon dioxide, which may be a native silicon dioxide.

In one embodiment, the semiconductor device 30 including the semiconductor substrate 32 and the tunnel dielectric layer 34 is placed into a vacuum environment and will remain in the vacuum environment at least until the completion of the nanocluster formation process. In another embodiment, the semiconductor device 30 is placed in the vacuum environment before formation of the tunnel dielectric layer 34 and is not removed from the vacuum environment at least until all the nanoclusters are formed. However, as discussed further in regards to FIG. 3, if the nanoclusters being formed are made of a material that will not react with the air to form a native oxide, then the semiconductor device 30 does not need to be kept in a vacuum environment during nanoclusters formation. In other words, after each deposition or anneal the semiconductor device 30 can be taken out of a vacuum environment, if the semiconductor device 30 was even in such an environment during the deposition or anneal.

In the embodiment shown and described in accordance with the figures, the vacuum environment is a CVD tool. In other embodiments, the vacuum environment can be any other deposition tool, such as an ALD or a PVD tool.

After forming the tunnel dielectric layer 34 and placing the semiconductor device 30 in the vacuum environment, a first flux of atoms 36 is flown into the vacuum environment as shown in FIG. 2. In an embodiment where the nanoclusters being formed will include silicon, the first flux of atoms 36 may be silane or disilane. If the nanoclusters being formed will include germanium, the first flux of atoms 36 may be germane or digermane. When the first flux of atoms 36 is flown, first adatoms 38 are formed on the tunnel dielectric layer 34. The first adatoms 38 may be single atoms of an element, such as silicon if silane or disilane is used as the first flux of atoms 36, or may combine to form dimers or trimers. The trimers or dimers may disintegrate into dimer or monomers, respectively. Enough of the first adatoms 38 may combine to form first nuclei 42, which do not disintegrate into any form of the first adatoms 38 (i.e., monomers, dimers, or trimers). Some nuclei may combine and form first nanoclusters 40 or may only attach to each other to form first doublets 43. Regardless, the purpose of the first flow of atoms 36 is to form the first nuclei 42 on the tunnel dielectric layer 34. As previously discussed, the first adatoms 38, the first nanoclusters 40, or the first doublets 43 may also be present on the tunnel dielectric layer 34. In one embodiment, the temperature while flowing the first flux of atoms 36 is between approximately 400 and 600 degrees Celsius. In one embodiment, the deposition time for the first nuclei formation is approximately 1 second to 2 minutes.

After forming the first nuclei 42, a first inert gas 44, such as argon, nitrogen or helium, is flown into the vacuum environment to form second nanoclusters 46, 48, and 50 during a first anneal, as illustrated in FIG. 3. In one embodiment, the anneal is performed for approximately 1 minute at a temperature between approximately 400 and approximately 1,000 degrees Celsius or more specifically, between approximately 600 and approximately 800 degrees Celsius. It is preferable to choose a time that reduces the number of adatoms present to zero. In one embodiment, the temperature of the first anneal is substantially the same as the temperature used in the first nuclei formation process.

If the materials used to form the nanoclusters grow a native oxide when exposed to air, such as silicon, the anneal should be an in situ anneal, because by breaking vacuum between the deposition and anneal processes native oxide will grow on the first nuclei 42, first nanoclusters 40, and doublets 43 preventing recrystallization during the first anneal. Instead, if an in situ anneal is performed any interconnected nanoclusters, such as the doublets 43, will break into separate entities, such as the second nanoclusters 48 and 50. However, if the nanoclusters being formed are made of a material that does not form a native oxide when exposed to air, such as a metal like gold, or platinum, vacuum can be broken because no native oxide will form and prevent the formation of the second nanoclusters 48, and 50.

During the first anneal the first nanoclusters 40 grow in size to form second nanoclusters 46 by consuming some of the first nuclei 42 by the phenomenon of Ostwald ripening, wherein the surface free energy of the system is minimized. The first anneal also results in larger exclusion zones being formed around nanoclusters. As a result any first adatoms 38 present on the dielectric surface will diffuse to the nearest nanocluster 46 contributing to its growth. The larger exclusion zones also inhibit coalescence by preventing new nanoclusters from forming within these areas during subsequent deposition. Thus, the first anneal reduces the formation of small nanoclusters relative in size to the second nanoclusters 46, 48 and 50 due to Ostwald ripening and depletion of adatoms on the surface. In addition, large nanoclusters relative in size to the second nanoclusters 46, 48 and 50 are prevented by inhibiting coalescence. Therefore, after the anneal, the second nanoclusters 46 all have approximately the same size so that the size distribution after the first anneal, shown in FIG. 3, is narrower than immediately after the first deposition, shown in FIG. 2.

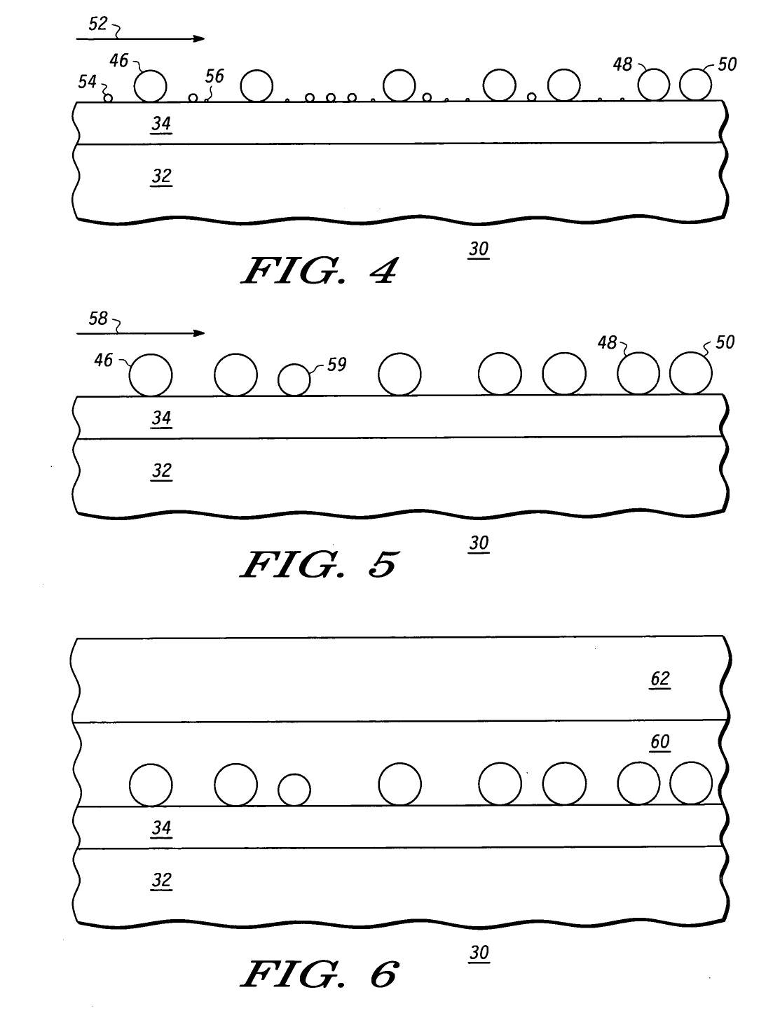

After the first anneal, a second flux of atoms 52 is flown into the vacuum environment as shown in FIG. 4. The second flux of atoms 52 can be any atoms used for the first flux of atoms 36, and in one embodiment, the second flux of atoms 52 is the same flux of atoms as the first flux of atoms 36. When the second flux of atoms 52 is flown, second adatoms 56 are formed on the tunnel dielectric layer 34. The second adatoms 56 may be single atoms of an element (i.e., monomers), such as silicon if silane or disilane is used as the second flux of atoms 52, or may combine to form dimers or trimers. The trimers or dimers may disintegrate into dimer or monomers, respectively. Some of the second adatoms 56 may combine to form second nuclei 54, which do not disintegrate into any form of the second adatoms 56 (i.e., monomers, dimers, or trimers), while some will merge with existing nanoclusters 46. Some nuclei may combine and form second nanoclusters (not shown) or may only attach to each other to form second doublets (not shown). Regardless, the purpose of the second flow of atoms 52 is to grow the existing nanoclusters 46 with suppressed formation of second nuclei 54 on the tunnel dielectric layer 34. As previously discussed, the second adatoms 56, the second nanoclusters (not shown), or the second doublets (not shown) may also be present on the tunnel dielectric layer 34. In one embodiment, the temperature while flowing the second flux of atoms 52 is between approximately 400 and 600 degrees Celsius. In one embodiment, substantially the same temperature is used when flowing the first flux of atoms 36 and the second flux of atoms 52. In one embodiment, the same process, such as CVD, is used when flowing first flux of atoms 36 and the second flux of atoms 52. In one embodiment, the deposition time for the second nuclei formation is approximately 20-200 seconds. In one embodiment, substantially the same time is used to form the first nuclei as is to form the second nuclei; in one embodiment, different times are used.

After forming the second nuclei 54, a second inert gas 58 such as argon, nitrogen or helium, is flown into the vacuum environment to form second nanoclusters 59 during a second anneal. In one embodiment, the first inert gas 44 is the same as the second inert gas 58 and in another embodiment, the first inert gas 44 is different than the second inert gas 58. In one embodiment, the anneal is performed for approximately 1 minute at a temperature between approximately 400 and approximately 1000 degrees Celsius or more specifically, between approximately 600 and approximately 800 degrees Celsius. It is preferable to choose a time that reduces the number of adatoms present to zero. In one embodiment, the temperature of the second anneal is substantially the same as the temperature used for the second nuclei formation process.

If the materials used to form the nanoclusters grow a native oxide when exposed to air, such as silicon, the anneal should be an in situ anneal to allow formation of the nanoclusters. But, if the materials used to form the nanoclusters do not grow a native oxide when exposed to air, such as a metal like gold or platinum, it does not matter if the anneal is in situ or is performed after breaking vacuum.

During the second anneal the second adatoms 56, the second nuclei 54, and the second nanoclusters will combine to form third nanoclusters 59. After the anneal, the third nanoclusters 59 all have approximately the same size so that the size distribution after the second anneal, shown in FIG. 5, is narrower than immediately after the second deposition, shown in FIG. 4. Since the first nanoclusters 46, 48, and 50 have undergone two anneal processes they will be larger than the third nanoclusters 59. Regardless, the size distribution of the first and third nanoclusters 46, 48, 50 and 59 is narrower than that achieved by prior art methods, because very few third nanoclusters 59 are formed. Like the first anneal, the second anneal also prevents the formation of small nanoclusters relative in size to the third nanoclusters 59. In addition, large nanoclusters relative in size to the third nanoclusters 59 are prevented by inhibiting coalescence. In one embodiment, the nanocluster density after the second anneal may be approximately_{—}1E12/cm2.

After forming the third nanoclusters 59, additional formation of nuclei and anneal steps can be performed if desired to increase the nanocluster size and change the size distribution. However, in a preferred embodiment, only two formation and anneal processes are performed, as described above.

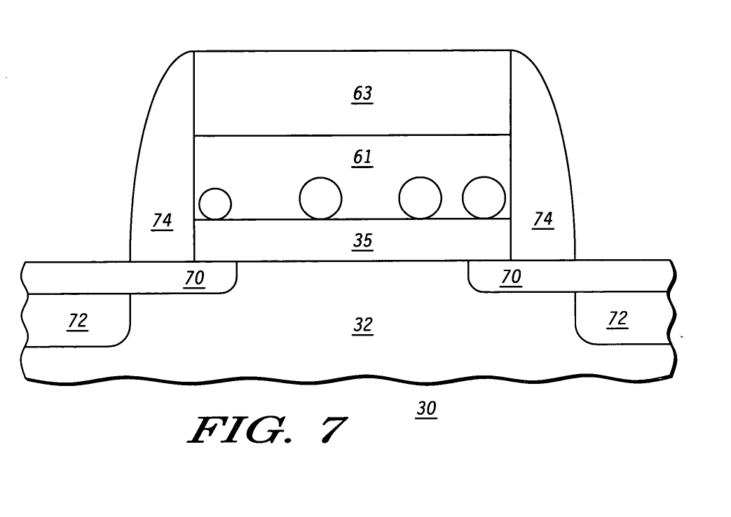

After forming the first and third nanoclusters 46, 48, 50 and 59, which are the final nanoclusters, additional processing to form a memory device may be performed. If a memory device is to be formed, after forming the final nanoclusters 46, 48, 50, and 59 over the tunnel dielectric layer 34, an optional passivation layer (not shown), which may contain nitrogen, can be formed over the final nanoclusters 46, 48, 50 and 59. A control dielectric layer 60, such as silicon dioxide, hafnium oxide, aluminum oxide, the like, and combinations of the above, is deposited over the final nanoclusters 46, 48, 50 and 59. After forming the control dielectric layer 60, a conductive material, such as polysilicon, is deposited to form the control electrode layer 62, as shown in FIG. 6.

As shown in FIG. 7, the control electrode layer 62, the control dielectric layer 60, the final nanoclusters 46, 48, 50 and 59, and the tunnel dielectric layer 34 are etched to form a control electrode 63, a control dielectric 61, and a tunnel dielectric 35 and to remove the final nanoclusters 46, 48, 50 and 59 that are not under the control electrode 63. After etching the layers, source/drain extensions 70 may be formed by shallow ion implantation. After forming the extensions, a dielectric layer, such as silicon nitride, is deposited over the semiconductor substrate and anisotropically etched to form spacers 74 adjacent the control electrode 63, the control dielectric 61, any remaining final nanoclusters 46, 48, 50 and 59, and the tunnel dielectric 35. The deep source/drain regions 72 may be formed using the spacers and the control electrode as a mask during deep ion implantation. The resulting memory device is especially useful as a non-volatile memory (NVM) device formed on a semiconductor substrate with (i.e., an embedded NVM device) or without (i.e., a stand-alone NVM device) logic transistors. Furthermore, the memory device is a data storage device.

By now it should be appreciated that there has been provided a cyclic deposition and anneal process to reduce size dispersion of nanocrystals. In one embodiment, the deposition and annealing is performed in an inert ambient without breaking vacuum. The method allows for increased nanocrystal density as well. The increased density and narrow size distribution increases the reliability of the semiconductor device as the NVM bitcells are scaled, especially for memory cells programmed by hot carrier injection, where the programmed charge is stored in a very small number of nanoclusters over the drain region. Since the charge stored is also dependent on the size of the nanoclusters, a narrow size distribution ensures similar charge per nanocluster and hence improved device reliability. Furthermore, if there is a process excursion in the factory that results in reduced nanocrystal density this process can be used to achieve the desired density despite the process excursion.

In the foregoing specification, the invention has been described with reference to specific embodiments. However, one of ordinary skill in the art appreciates that various modifications and changes can be made without departing from the scope of the present invention as set forth in the claims below. For example, although only one deposition process was used to form the nuclei, a two-step or multi-step deposition process can be used. Accordingly, the specification and figures are to be regarded in an illustrative rather than a restrictive sense, and all such modifications are intended to be included within the scope of the present invention.

Moreover, the terms “front”, “back”, “top”, “bottom”, “over”, “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. The terms “a” or “an”, as used herein, are defined as one or more than one. The term “plurality”, as used herein, is defined as two or more than two. The term another, as used herein, is defined as at least a second or more.

What is claimed is:

1. A method for forming nanoclusters comprising:
providing a semiconductor substrate;
forming a dielectric layer over the semiconductor substrate;
exposing the semiconductor substrate to a first flux of atoms to form first nuclei on the dielectric layer;
exposing the first nuclei to a first inert atmosphere after the exposing the semiconductor substrate to the first flux; and
exposing the semiconductor substrate to a second flux of atoms to form second nuclei after the exposing the first nuclei to an inert atmosphere.

2. The method of claim 1, wherein the exposing the semiconductor substrate to the first flux of atoms comprises forming the first nuclei by a method selected from the group consisting of chemical vapor deposition (CVD), atomic layer deposition (ALD), and physical vapor deposition (PVD).

3. The method of claim 1, wherein the exposing the semiconductor substrate to the second flux of atoms comprises forming the second nuclei by a method selected from the group consisting of chemical vapor deposition (CVD), atomic layer deposition (ALD), and physical vapor deposition (PVD).

4. The method of claim 1, wherein the exposing the semiconductor substrate to a first flux of atoms is performed at a first temperature, the exposing the first nuclei to a first inert atmosphere is performed at a second temperature, and the second temperature is greater than or equal to the first temperature.

5. The method of claim 1, wherein the exposing the semiconductor substrate to the first flux of atoms comprises exposing the substrate to a chemistry selected from the group consisting of disilane, silane, germane and digermane.

6. The method of claim 5, wherein the exposing the semiconductor substrate to the second flux of atoms comprises exposing the substrate to a chemistry selected from the group consisting of disilane, silane, germane and digermane.

7. The method of claim 1, wherein exposing the first nuclei to a first inert atmosphere comprises exposing the first nuclei to an element selected from the group consisting of nitrogen, argon and helium.

8. The method of claim 1, wherein the exposing the semiconductor substrate to a first flux of atoms, the exposing the first nuclei to a first inert atmosphere, and the exposing the semiconductor substrate to a second flux of atoms occurs within a same tool without breaking vacuum.

9. The method of claim 1, further comprising exposing the nuclei to a second inert atmosphere after the exposing the semiconductor substrate to a second flux of atoms.

10. The method of claim 9, wherein the exposing the semiconductor substrate to a second flux of atoms is performed at a third temperature, the exposing the second nuclei to a second inert atmosphere is performed at a fourth temperature, and the fourth temperature is greater than or equal to the third temperature.

11. The method of claim 10, wherein the exposing the semiconductor substrate to a first flux of atoms is performed at a first temperature, the exposing the first nuclei to a first inert atmosphere is performed at a second temperature, and the first temperature is approximately equal to the third temperature and the second temperature is approximately equal to the fourth temperature.

12. The method of claim 11, wherein the first temperature and the third temperature is between 400 and 600 degrees Celsius; and the second temperature and the fourth temperature are between 400 and 1,000 degrees Celsius.

13. A method of forming nanoclusters, comprising:
providing a substrate;
forming a dielectric layer overlying the substrate;
placing the substrate in a deposition chamber;
flowing a first precursor gas into the deposition chamber during a first phase to nucleate first nanoclusters on the dielectric layer;
flowing a second precursor gas into the deposition chamber during a second phase to nucleate second nanoclusters on the dielectric layer; and
performing a first anneal after the flowing the first precursor gas and before the flowing the second precursor gas.

14. The method of claim 13, further comprising performing a second anneal after flowing the second precursor gas.

15. The method of claim 13, wherein the first precursor gas and the second precursor gas comprise substantially a same gas.

16. The method of claim 15, wherein the first precursor gas and the second precursor gas are different gases.

17. The method of claim 13, wherein the first precursor gas and the second precursor gas are selected from the group consisting of disilane, silane, germane and digermane.

18. The method of claim 13, wherein the flowing a first precursor gas, the flowing a second precursor gas, and the performing a first anneal are performed in vacuum.

19. A method of forming nanoclusters, comprising:
providing a substrate;
forming a dielectric layer overlying the substrate;
placing the substrate in a deposition chamber;
flowing a first precursor gas into the deposition chamber during a first phase to nucleate first nanoclusters on the dielectric layer with first predetermined conditions existing within the deposition chamber for a first time period;
ending the flowing of the first precursor gas into the deposition chamber;
performing an intermediate anneal to grow the first nanoclusters; and
flowing a second precursor gas into the deposition chamber during a second phase to nucleate second nanoclusters on the dielectric layer with second predetermined conditions existing within the deposition chamber for a second time period.

20. The method of claim 19, wherein the first precursor gas and the second precursor gas comprise a same gas.
